(19) United States
(12) Patent Application Publication
(10) Pub. No.: US 2014/0292417 A1
(43) Pub. Date: Oct. 2, 2014

(54) VOLTAGE-CONTROLLED OSCILLATOR MODULE AND PHASE-LOCKED LOOP DEVICE INCLUDING THE SAME

(71) Applicant: ASAHI KASEI MICRODEVICES CORPORATION, Tokyo (JP)

(72) Inventors: David Canard, Colombelles (FR); Matthieu Lecuyer, Colombelles (FR)

(73) Assignee: ASAHI KASEI MICRODEVICES CORPORATION, Tokyo (JP)

(21) Appl. No.: 14/226,886

(22) Filed: Mar. 27, 2014

(30) Foreign Application Priority Data
Mar. 28, 2013 (EP) 13305382.7

(51) Int. Cl. H03L 7/00; H03L 7/08

(52) U.S. Cl. CPC H03L 7/00; H03L 7/08
USPC 331/17

(57) ABSTRACT

A voltage-controlled oscillator (VCO) module combines a low VCO-gain value with compensation for large frequency drifts. The VCO module comprises a VCO circuit and a time-integrator. The VCO circuit is fed with a first frequency tuning voltage and a second frequency tuning voltage which is produced by the time-integrator from the first frequency tuning voltage. In some embodiments, the time-integrator may be comprised of a transconductor connected in series with a capacitor, and the transconductor may have a linear operation range with low slope or zero-slope, located between two side ranges with deeper slope.

This application claims the priority and benefit of EP patent application no. 13305382.7, filed on Mar. 28, 2013, to Asahi Kasei Microdevices Corporation of Japan, entitled “Voltage-Controlled Oscillator Module and Phase-Locked Loop Device Including the Same,” which is hereby incorporated by reference in its entirety.

### TECHNICAL FIELD

The invention relates generally to a voltage-controlled oscillator (VCO) module and a phase-locked loop (PLL) device which includes such a VCO module.

### BACKGROUND

A major feature of a voltage-controlled oscillator is its gain value, defined as the derivative of the frequency of the VCO signal which is outputted by the oscillator, with respect to an input direct voltage. This derivative is commonly called VCO gain and is denoted K_{VCO}.

However, the frequency of the VCO signal may drift due to several causes, and a temperature variation of the VCO circuit is often a main one of these causes. Suitable tuning of the input direct voltage allows compensating for the frequency drift, so that the VCO signal appears to be constant in frequency.

In frequency synthesizers based on phase-locked loops including VCO circuits, low K_{VCO} values are preferred because possible noise on the frequency tuning voltage can lead to less noise in the phase of the VCO signal when the K_{VCO} value is low, the charge-pump current of the phase-locked loop can be larger, thus reducing the phase noise within the phase-locked loop, and a low K_{VCO} value makes easier the integration of a loop filter within the phase-locked loop.

However, a low K_{VCO} value may be insufficient for enabling compensation for large frequency drifts caused by, for example, temperature variations.

Solutions have been implemented for combining the use of a low K_{VCO} value together with enabling compensation for possible large frequency drifts. One of these solutions implements a VCO module that comprises a VCO circuit adapted for outputting the VCO signal, and provided with first and second voltage inputs both designed for tuning the frequency of the VCO signal; and a compensation circuit that has an output connected to the second voltage input of the VCO circuit.

The first voltage input of the VCO circuit may correspond to a small value for the VCO gain when required, and may operate as the usual input for the VCO circuit. In particular, this first voltage input may participate in a feedback loop of a frequency synthesizer based on a phase-locked loop. The second voltage input of the VCO circuit may be dedicated to compensating for the large frequency drifts. The compensation circuit comprises parameter sensors, including a temperature sensor, and components which are selected for matching frequency drifts of the VCO circuit due to deviations of the parameters. The compensation circuit thus continuously analog-tunes the voltage that is transmitted at the second input of the VCO circuit so as to compensate for the frequency drifts. However, such compensation is difficult and expensive to implement. For example, it can require a precise knowledge of all parameters that may cause frequency drifts, and the maximum possible deviation of each of these parameters.

In other solutions, the VCO circuit is provided with a digitally controlled capacitor bank, and the VCO module also comprises a temperature sensor and a re-calibration unit which is suitable for digitally controlling the capacitance value of the capacitor bank. The re-calibration unit updates the capacitance value when the deviation between the currently sensed temperature and a prior temperature used for the previous updating rises above a threshold. However, such operation generates significant disturbance of the VCO signal at each updating event, and is not compatible with continuous delivery of the VCO signal.

Therefore, one object of the present invention is to propose a novel VCO module that is provided with compensation for frequency drift, but without the drawbacks of the above solutions. For example, the invention aims at combining the use of a low K_{VCO} value together with enabling compensation for large drifts of the VCO signal frequency in a low-cost and efficient manner.

### BRIEF SUMMARY

To achieve these and other objects of the invention, in some embodiments, a VCO module comprises a VCO circuit with first and second inputs for receiving respective frequency tuning voltages, and also a compensation circuit connected to the second voltage input of the VCO circuit. In the VCO module, the compensation circuit includes an integrator having an input connected to the first voltage input of the VCO circuit, and an output connected to the output of the compensation circuit. The integrator is configured to produce, at the integrator output, a voltage based on integration over time of effective values obtained from values of a voltage transmitted at the input of the integrator.

Hence, in a VCO module according to some embodiments, the compensation circuit continually analog-tunes the voltage applied to the second input of the VCO circuit, so that the operation of the VCO circuit is not interrupted. The VCO signal can thus be continually delivered. This tuning performed by the compensation circuit can compensate for large frequency drifts, while the first voltage input of the VCO circuit is used for operations with a low K_{VCO} value. The drift compensation performed by using the second voltage input of the VCO circuit takes over from that produced by using the first voltage input when the frequency drift is too large with respect to the K_{VCO} value. In this way, any frequency drift can be compensated for, and small frequency drifts can still be compensated for by implementing an effective low K_{VCO} value.

In some embodiments, the integrator may be adapted so that each effective value is obtained as a function of the value of the voltage transmitted at the input of the integrator, where this function has a reduced slope within a linear operation range for the value of the voltage transmitted at the input of the integrator. The linear operation range is finite in length on both low value side and high value side. In addition, the function slope is steeper out of the linear operation range when compared to within the linear operation range, and is devoid of any change in the slope sign. Furthermore, the function for determining the effective value equals zero for at least one value of the voltage transmitted at the input of the integrator, within the linear operation range. In this way, frequency drift compensation using the second voltage input of the VCO circuit and usual control of the frequency with a low K_{VCO} value can be performed at the same time while being functionally almost separated.

In some embodiments, the slope of the effective value as function of the value of the voltage transmitted at the first integrator input may have at least one value out of the linear operation range—particularly, higher than within this linear operation range by a factor greater than two, and preferably by five or ten.

In some embodiments, the integrator may be designed so that the function which determines the effective value equals zero over the whole linear operation range. Thus, no frequency drift compensation using the second voltage input is effective as long as the voltage at the first voltage input of the VCO circuit has not exceeded the limits of the linear operation range.

In some embodiments, the integrator may be provided with two reference voltage inputs suitable for tuning two limits of the linear operation range.

In some embodiments, the integrator may include a transconductor and a capacitor connected in series, and an intermediate node between the transconductor and the capacitor. This node is connected to the output of the integrator. In such embodiments, a voltage input of the transconductor forms the input of the integrator, and values of a current output by the transconductor into the capacitor form the effective values.

In some embodiments, a VCO-gain of the VCO circuit related to the first voltage input may be less than another VCO-gain of the VCO circuit related to the second voltage input, each VCO-gain being a derivative of the frequency of the VCO signal with respect to the value of the voltage transmitted at the corresponding first or second voltage input, while the value transmitted at the other one of the first and second voltage inputs is kept constant.

In some embodiments, a phase-locked loop device includes a VCO module, an example of which was described above; a phase comparison system connected to receive a reference clock phase and a phase derived from the VCO signal output by the VCO module, this phase comparison system adapted to produce a comparison signal representative of a difference between the reference clock phase and the phase derived from the VCO signal; a loop filter connected in series and downstream with the phase comparison system so as to receive at an input the comparison signal, and adapted to produce at an output a voltage corresponding to the comparison signal filtered; and a frequency converter adapted to produce the phase derived from the VCO signal by frequency division or frequency elevation with a fixed division or elevation factor.

In the PLL device of some embodiments, an output of the loop filter is connected to the first voltage input of the VCO circuit, so that the VCO circuit from this first voltage input, the frequency converter, the phase comparison system, and the loop filter pertain to a first feedback loop within the PLL device, and the integrator, the VCO circuit from its second voltage input, the frequency converter, the phase comparison system, and the loop filter additionally pertain to a second feedback loop within the PLL device.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of the specification, illustrate embodiments of the invention and together with the description serve to explain the principles of the invention. In the drawings:

FIG. 1 is a block diagram of a VCO module according to some embodiments;

FIG. 2 is an electric diagram of a VCO circuit possibly used in some embodiments;

FIG. 3a is block diagram of a VCO module according to some embodiments, and

FIG. 3b is a chart relating to a transconductor used, for example, in the embodiment of FIG. 3a;

FIG. 4 is an electric diagram of a transconductor that may be suitable for obtaining the chart of FIG. 3b; and

FIG. 5a is a block diagram of a PLL device according to some embodiments, and FIG. 5b is a corresponding frequency analysis diagram.

Similar reference numbers which are indicated in different figures denote similar elements of elements with similar functions. In addition, components with well-known function and operation may not be described in detail.

### DETAILED DESCRIPTION

Reference will now be made in detail to embodiments, examples of which are illustrated in the accompanying drawings. In the following detailed description, numerous non-limiting specific details are set forth in order to assist in understanding the subject matter presented herein. It will be apparent, however, to one of ordinary skill in the art that various alternatives may be used without departing from the scope of the present invention and the subject matter may be practiced without these specific details.

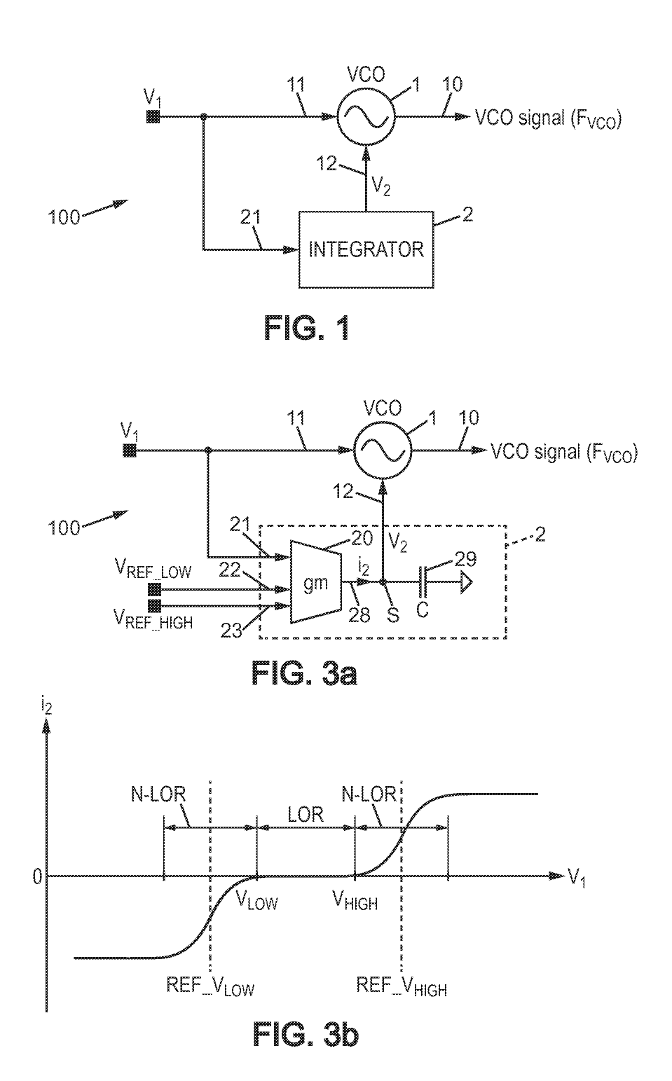

With reference to FIG. 1, in some embodiments, the VCO module 100 comprises a VCO circuit 1 and an integrator 2. The VCO circuit 1 is provided with an output 10 for delivering the VCO signal, and two voltage inputs 11 and 12. Both inputs 11 and 12 are arranged to receive respective direct voltages V₁ and V₂, so that the frequency F_{VCO} of the VCO signal varies as a function of both V₁- and V₂-values. In an example, for one operation mode of the VCO module 100, the V₁-derivative of the frequency F_{VCO} while V₂-value is kept constant may be greater than the V₂-derivative of the frequency F_{VCO} with a constant V₁-value. In other words, the frequency of the VCO signal delivered by the VCO circuit 1 may depend more steeply on V₁-variations than V₂-variations, at least in a linear operation range. The opposite may be true outside of the linear operation range.

According to some embodiments, the V₂-voltage transmitted at the input 12 of the VCO circuit is produced from the V₁-voltage transmitted at the input 11 using the integrator 2. Thus, an input 21 of the integrator 2 is connected to the voltage input 11 of the VCO circuit 1, so that the integrator 2 is fed at input with the V₁-voltage at the same time as the VCO circuit 1. The integrator 2 is also connected at an output to the voltage input 12 of the VCO circuit 1. Hence, the integrator 2 produces the V₂-voltage from the V₁-voltage, and the V₂-voltage thus produced is also fed into the VCO circuit 1.

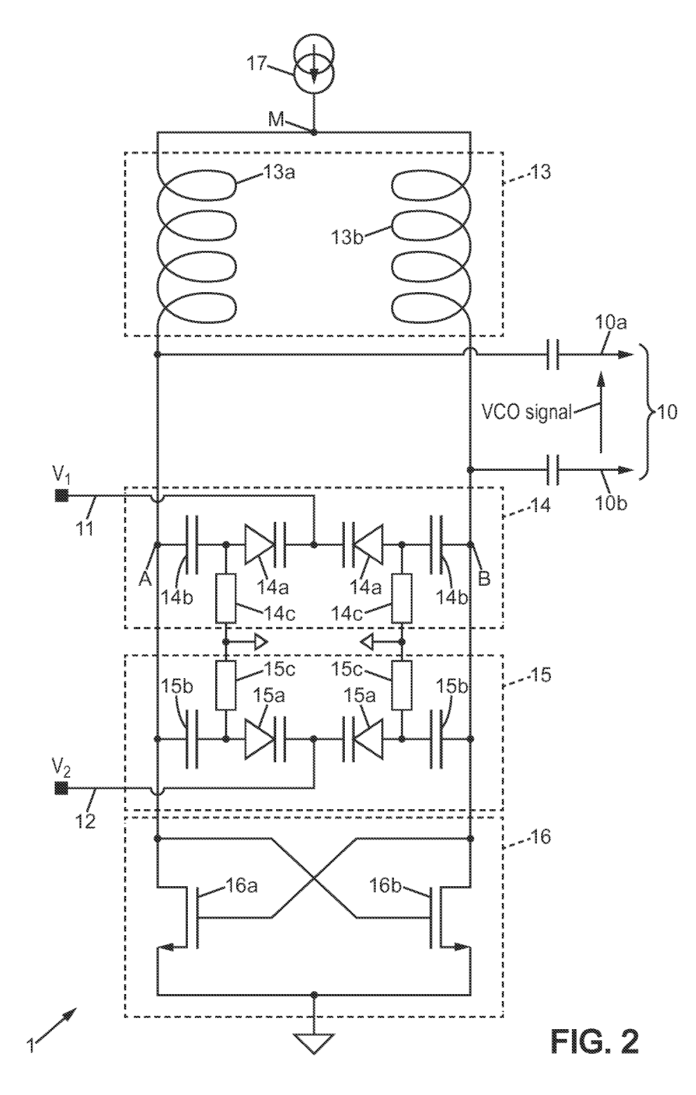

FIG. 2 shows a possible structure for the VCO circuit 1 according to some embodiments. The VCO circuit 1 shown in FIG. 2 is comprised of an inductor block 13, two capacitors blocks 14 and 15, and a negative resistance block 16, which are connected in parallel with each other between nodes A and B. The whole structure is energy-fed by a direct current source 17, and may have a symmetric composition for improving common mode rejection. Thus, the inductor block 13 may be comprised of two coils 13a and 13b connected in series, with the mid-point M connected to the output of the current source 17. Negative resistance block 16 may be comprised of two N-transistors 16a and 16b with the gate of each one connected to the collector of the other one, and the emitters of both transistors 16a and 16b connected to a common reference node represented by a triangle. The negative resistance block 16 compensates for energy losses occurring elsewhere in the VCO circuit 1, for example, in the inductor block 13 and the capacitor blocks 14 and 15.

The capacitor block 14 may be comprised of two branch segments which connect the voltage input 11 respectively to the nodes A and B. Reference 14a denotes varactors which may be based in a usual manner on diode or FET-transistor components. Varactors 14a or each branch segment may be identical, and both capacitors 14b may also be equal to each other. Each branch segment is also provided with a polarization resistance 14c. Due to the varactor operation, the overall capacitance value of the capacitor block 14 changes upon varying the value of the direct voltage V₁.

In some embodiments, capacitor block 15 may have a structure similar to that of capacitor block 14, with reference numbers 15a-15c having respective meanings similar to 14a-14c previously introduced. In some embodiments, the varactors 14a and 15a may be designed so that the capacitance value of the varactors 15a is a function of the V₂-voltage, which is steeper than that of the capacitance value of the varactors 14a depending on the V₁-voltage. For consistency, the capacitance value of the capacitors 15b may also be higher than that of the capacitors 14b.

In some embodiments, the VCO signal which is output by the VCO circuit 1 is the AC-voltage existing between both nodes A and B. Thus, the output 10 for the VCO signal is of differential type. The capacitors arranged on both lines 10a and 10b of the differential output 10 prevent direct current originating from the current source 17 from flowing away through the output 10, but they may have no function with respect to the VCO signal.

With reference to FIG. 3a, in some embodiments, the integrator 2 may be comprised of a transconductor 20 connected in series with a capacitor 29. Reference “gm” denotes the differential transconductance value of the transconductor 20, and C is the capacitance value of the capacitor 29. The transconductor 20 operates as an entrance stage of the integrator 2, thus transforming the V₁-voltage received at the input 21 into a current i₂ delivered at the transconductor output 28 and fed into the capacitor 29. The voltage input 12 of the VCO circuit 1 is then connected to a node S intermediate between the output 28 of the transconductor 20 and the capacitor 29.

The transconductor 20 may have a non-linear chart as shown for example in FIG. 3b. This chart shows the variations of the current i₂ as a function of the input voltage V₁. In a middle range of this chart, these variations are linear with a small slope gm, and this small slope is located between two side ranges where the slope is deeper. The middle range where the slope is reduced has been called a linear operation range in the general description, and it is here denoted LOR. The side ranges where the slope is deeper are denoted N-LOR (for “non-linear operation ranges”). Two reference voltages denoted V_{REF}_{_{—}}_{LOW} and V_{REF}_{_{—}}_{HIGH} indicate respective center positions for the N-LOR ranges along the V₁-axis. For example, the V₁-derivative of the i₂-current for some of the V₁-values in the N-LOR ranges may be greater than within the LOR range by a factor of more than two, or preferably more than five or ten. The reference voltages V_{REF}_{_{—}}_{LOW} and V_{REF}_{_{—}}_{HIGH} may be set using suitable additional inputs 22 and 23 provided to the transconductor 20 (see FIG. 3a). Thus, changing the reference voltages V_{REF}_{_{—}}_{LOW} and V_{REF}_{_{—}}_{HIGH} allows tuning of the limits V_{LOW} and V_{HIGH} of the linear operation range. The slope gm of the variations of the current i₂ as a function of the voltage V₁ is constant in sign over the whole LOR and N-LOR ranges, but possibly reaches zero-slope. In addition, due to saturation effects, the current i₂ is limited in value on both external sides of the non-linear operation ranges, i.e., for V₁-values that are much less than V_{REF}_{_{—}}_{LOW} or much larger than V_{REF}_{_{—}}_{HIGH}.

The current i₂ is zero for at least one V₁-value in the LOR range, which may be the center V₁-value of this range.

In some embodiments, the current i₂ may be zero over the whole LOR range, so that variations of the V₁-voltage within the LOR range have no effect on the V₂-voltage. Thus, no alteration of the frequency F_{VCO} of the VCO signal may be caused through the voltage input 12 of the VCO circuit 1. However, the V₁-voltage is still effective for tuning the frequency F_{VCO} of the VCO signal due to the voltage input 11 of the VCO circuit 1.

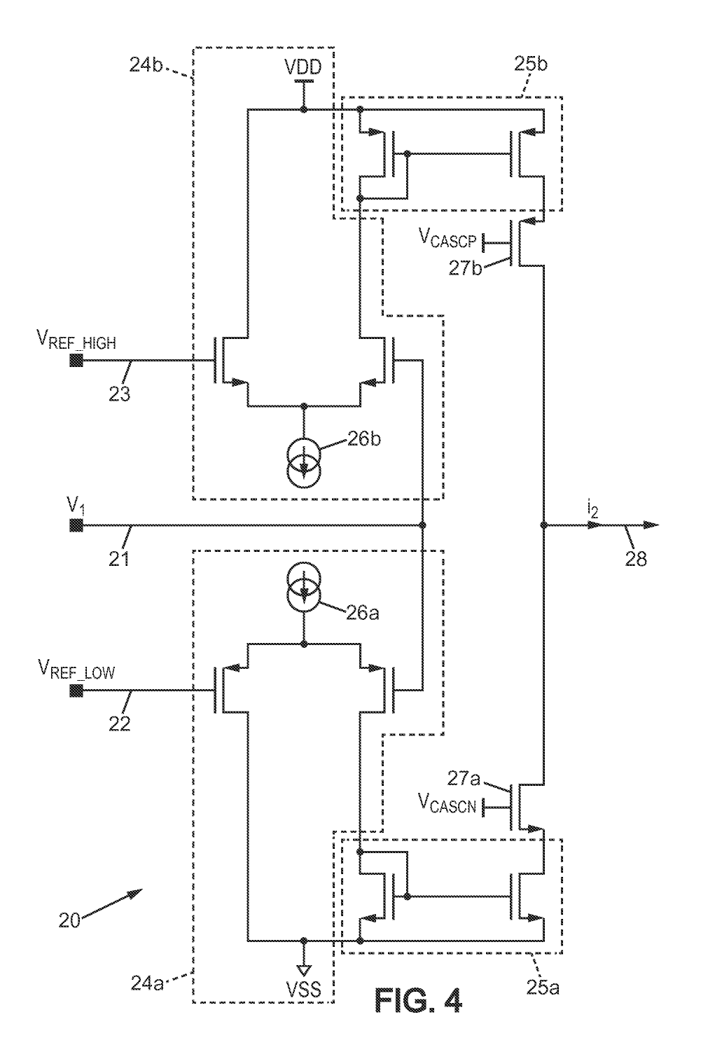

For some embodiments, FIG. 4 shows a possible structure for the transconductor 20. It may comprise a P-transistor differential pair 24a, with a first gate input connected to the transconductor input 21, and a second gate input intended for receiving the lower reference voltage V_{REF}_{_{—}}_{LOW}; a first current-mirror assembly 25a, which is connected for extracting from the transconductor output 28 a current which reproduces a first internal current flowing in the branch of the P-transistor differential pair 24a related to the first gate input; an N-transistor differential pair 24b, with another first gate input also connected to the transconductor input 21, and another second gate input intended for receiving the upper reference voltage V_{REF}_{_{—}}_{HIGH}; and a second current-mirror assembly 25b connected to supply the transconductor output 28 with a current which reproduces a second internal current flowing in the branch of the N-transistor differential pair 24b related to the first gate input of this latter N-transistor differential pair.

The second gate inputs of the transistor differential pairs 24a and 24b thus form the additional inputs 22 and 23, respectively. References 26a and 26b denote current sources arranged for current-supplying the transistor differential pairs 24a and 24b. VDD and VSS respectively denote upper and lower voltage supply sources. Optionally, transistors 27a and 27b may be used with a cascode arrangement for increasing the output parallel-impedance of the transconductor 20. V_{CASCN} and V_{CASCP} denote polarization voltage supply sources used for setting the respective gate voltages of the transistors 27a and 27b.

When the V₁-voltage value is between the reference voltage values V_{REF}_{_{—}}_{LOW} and V_{REF}_{_{—}}_{HIGH}, or more precisely between the LOR range limits V_{LOW} and V_{HIGH}, zero current is extracted from or supplied to the transconductor output 28, so that the output current i₂ exhibits very low noise or nearly zero noise. Such low noise on the i₂-current is even more reduced because no internal current is also flowing in the branches of the N- and P-transistor differential pairs 24a and 24b, which are related to the first gate inputs for operation within the LOR range.

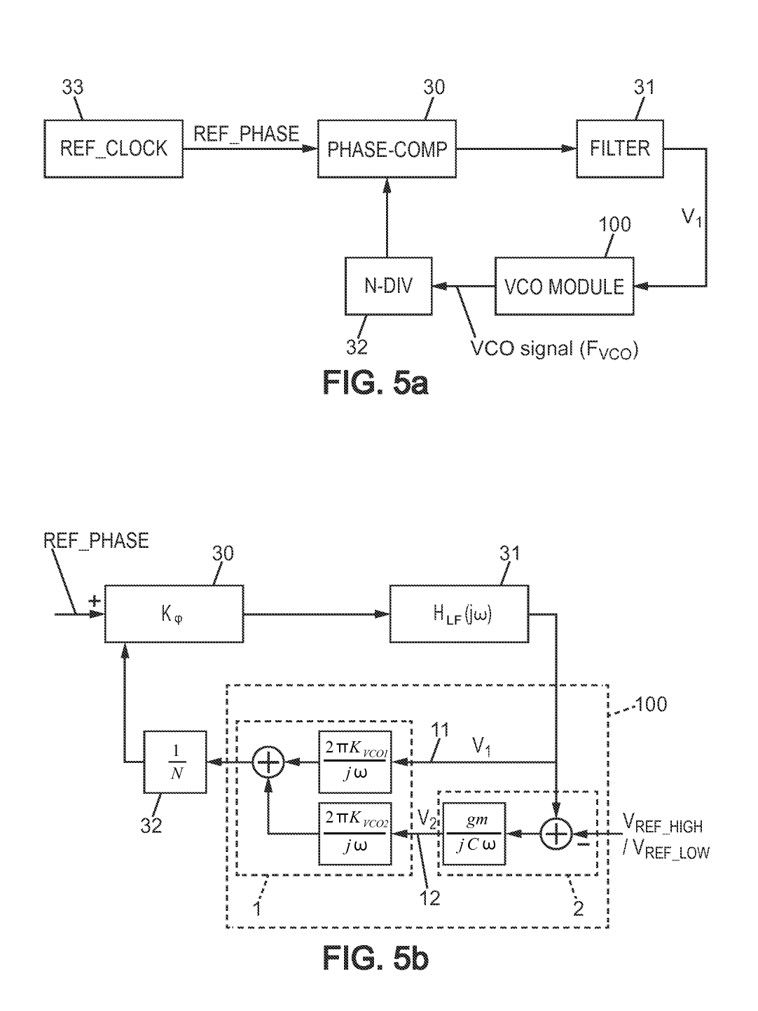

FIG. 5a shows a phase-locked loop device incorporating the VCO module 100 according to some embodiments. The additional references in this figure represent the following:
30: a phase comparison system denoted PHASE_COMP, with phase comparison gain K_{φ};
31: a loop filter denoted FILTER, with transfer function H_{LF}(jω), where j is the complex number unit and ω is a Fourier component pulsation;
32: a frequency converter, which may be a N-divider or N-multiplier, N being a division or multiplication factor greater than unity; and
33: a reference clock denoted REF_CLOCK, which supplies a reference clock phase REF_PHASE.

In this example PLL device, the frequency converter 32 decreases or increases the frequency of the VCO signal by the N-factor. The phase comparison system 30 produces a comparison signal which represents the difference between the reference clock phase and the phase of the signal delivered by the frequency converter 32. Then, the loop filter 31 operates a time-filtering onto the comparison signal for delivering the V₁-voltage. This signal is then fed into the VCO module 100.

FIG. 5b corresponds to FIG. 5a and shows the combination of the transfer functions for the various components of the PLL device according to some embodiments.

Functionally, this PLL device implements two feedback loops having shared components, with the following loop assignment: for the first feedback loop, the VCO circuit 1 from its voltage input 11, the frequency converter 32, the phase comparison system 30, and the loop filter 31; for the second feedback loop, the VCO circuit 1 from its voltage input 12, the frequency converter 32, the phase comparison system 30, the loop filter 31, and the integrator 2.

Within the second feedback loop, the integrator 2 continually adjusts the V₂-voltage so that the V₁-voltage remains within the LOR range of FIG. 3b. Hence, no interruption is caused in the delivery of the VCO signal while combining a small value for the V₁-derivative of the frequency F_{VCO} together with compensation for large frequency drifts.

As an example, a N-divider denoted N-DIV is used for the frequency converter 32, so that the whole PLL device is a frequency elevator.

Then, the open-loop transfer function of the PLL device is as follows, as a function of the complex parameter jω:

$$O L ( j ω ) = \frac{2 π \cdot {K}_{ϕ} \cdot {H}_{LF} ( j ω ) \cdot {K}_{VCO 1}}{N \cdot j ω} \cdot [ 1 + \frac{gm \cdot {K}_{VCO 2}}{j C ω \cdot {K}_{VCO 1}} ]$$

where K_{VCO 1} is the V₁-derivative of the frequency F_{VCO} of the VCO signal at constant V₂-voltage, and K_{VCO 2} is the V₂-derivative of the same frequency F_{VCO} at constant V₁-voltage. As mentioned, K_{VCO 1} may preferably be smaller than K_{VCO 2}.

Therefore, the condition for operation stability of the PLL device may be:

$$\frac{gm \cdot {K}_{VCO 2}}{C ω \cdot {K}_{VCO 1}} << 1 , e . g . ,$$

that the first member ratio is much less than unity for a value of the pulsation ω yielding an open-loop gain equal to unity in the first feedback loop. Practically, the first member ratio may be less than 0.1 for such a ω-value.

Advantages of the present embodiments include the benefit that no prior knowledge of the frequency drift causes may be necessary, compensation is efficient for any cause of the frequency drift and not only temperature-caused drifts, no circuit matching is required, the VCO signal is continually available even when large drift compensation is being performed, a low value of the VCO-gain is effective, and low phase noise is generated. The present embodiments which have been described above may be adapted with respect to some aspects while retaining at least some of these advantages. Additionally, the VCO module and PLL device may be embodied either in an analog mode as described, or in a digital mode, which one of ordinary skill in the art will be able to derive.

1. A voltage-controlled oscillator (VCO) module provided with compensation for frequency drift, comprising:
a VCO circuit configured to output a VCO signal, and provided with first and second voltage inputs both for tuning a same frequency (F_{VCO}) of the VCO signal; and
a compensation circuit comprising
an output connected to the second voltage input of the VCO circuit,
an integrator having an input connected to the first voltage input of the VCO circuit and an output connected to the output of the compensation circuit, the integrator configured to produce at the integrator output a voltage V₂ based on an integration over time of effective values obtained from a voltage V₁ at the input of the integrator,
wherein the integrator is configured such that each of the effective values is obtained as a function of the value of the voltage V₁ at the input of the integrator,
a slope of the function being reduced within a linear operation range for the value of the voltage V₁ at the input of the integrator, the linear operation range being finite in length on both a low value side and a high value side, the function slope being steeper out of the linear operation range than within the linear operation range, and being devoid of any change in slope sign, and
the function equalling zero for at least one value of the voltage V₁ at the input of the integrator within the linear operation range.

2. The VCO module of claim 1, wherein the integrator is configured such that the function determining the effective values equals zero over the linear operation range.

3. The VCO module of claim 1, wherein the integrator is provided with two reference voltage inputs for tuning two limits of the linear operation range.

4. The VCO module of claim 1, wherein the integrator comprises a transconductor and a capacitor connected in series, and a node intermediate between the transconductor and the capacitor, the node being connected to the output of the integrator, a voltage input of the transconductor forming the input of the integrator, and values of a current i₂ output by the transconductor into the capacitor forming the effective values.

5. The VCO module of claim 4, wherein the transconductor comprises:
a P-transistor differential pair with a first gate input connected to the voltage transconductor input, and a second gate input for receiving a lower reference voltage V_{REF}_{_{—}}_{LOW} to set a lower limit V_{LOW} of the linear operation range;
a first current-mirror assembly connected to extract from the transconductor output a current which reproduces a first internal current flowing in a branch of the P-transistor differential pair related to the first gate input of said P-transistor differential pair;
an N-transistor differential pair with another first gate input connected to the voltage transconductor input, and another second gate input for receiving an upper reference voltage V_{REF}_{_{—}}_{HIGH} to set an upper limit V_{HIGH} of the linear operation range; and
a second current-mirror assembly connected to supply the transconductor output with a current which reproduces a second internal current flowing in a branch of the N-transistor differential pair related to the another first gate input of the N-transistor differential pair.

6. The VCO module of claim 1, wherein a VCO-gain K_{VCO 1} of the VCO circuit related to the first voltage input is less than another VCO-gain of the VCO circuit related to the second voltage input, each VCO-gain being a derivative of the frequency F_{VCO} of the VCO signal with respect to the value of the voltage at the corresponding one of the first or second voltage input while the value at the other one of the first and second voltage inputs is constant.

7. A phase-locked loop (PLL) device, comprising:
a voltage-controlled oscillator (VCO) module provided with compensation for frequency drift, comprising
a VCO circuit configured to output a VCO signal, and provided with first and second voltage inputs both for tuning a same frequency (F_{VCO}) of the VCO signal; and
a compensation circuit comprising
an output connected to the second voltage input of the VCO circuit,
an integrator having an input connected to the first voltage input of the VCO circuit and an output connected to the output of the compensation circuit, the integrator configured to produce at the integrator output a voltage V₂ based on an integration over time of effective values obtained from a voltage V₁ at the input of the integrator,
wherein the integrator is configured such that each of the effective values is obtained as a function of the value of the voltage V₁ at the input of the integrator,
a slope of the function being reduced within a linear operation range for the value of the voltage V₁ at the input of the integrator, the linear operation range being finite in length on both a low value side and a high value side, the function slope being steeper out of the linear operation range than within the linear operation range, and being devoid of any change in slope sign, and
the function equalling zero for at least one value of the voltage V₁ at the input of the integrator within the linear operation range;
the phase-locked loop device further comprising
a phase comparison system connected to receive a reference clock phase and a phase derived from the VCO signal output by the VCO module, the phase comparison system configured to produce a comparison signal representative of a difference between the reference clock phase and the phase derived from the VCO signal;
a loop filter connected in series and downstream with the phase comparison system to receive at an input the comparison signal, and configured to produce at an output a voltage corresponding to the comparison signal filtered; and
a frequency converter configured to produce the phase derived from the VCO signal by frequency division or frequency elevation with fixed division or elevation factor,
wherein an output of the loop filter is connected to the first voltage input of the VCO circuit, so that the VCO circuit from the first voltage input, the frequency converter, the phase comparison system, and the loop filter pertain to a first feedback loop within the PLL device, and the integrator, the VCO circuit from the second voltage input, the frequency converter, the phase comparison system, and the loop filter pertain to a second feedback loop within the PLL device.
